(19) United States
(12) Patent Application Publication
(10) Pub. No.: US 2009/0004856 A1
(43) Pub. Date: Jan. 1, 2009

(54) METHOD OF FORMING CONTACT PLUG IN SEMICONDUCTOR DEVICE

(75) Inventors: Eun Soo Kim, Incheon-Si (KR); Jung Geun Kim, Seoul (KR); Seung Hee Hong, Seoul (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-Si (KR)

(21) Appl. No.: 11/950,500

(22) Filed: Dec. 5, 2007

(30) Foreign Application Priority Data
Jun. 28, 2007 (KR) 2007-64306

(51) Int. Cl. H01L 21/44

(52) U.S. Cl. 438/675; 257/E21.476

(57) ABSTRACT

A method of forming a contact plug in a semiconductor device comprising etching an interlayer insulating layer to form a patterned interlayer insulating layer having contact holes such that a distance between upper portions of the contact holes is minimized; forming a first insulating layer including a overhang portion for wrapping an upper portion of the patterned interlayer insulating layer; forming a liner-shaped second insulating layer on the patterned interlayer insulating layer including the first insulating layer, the second insulating layer being formed from material having a selectivity which differs from that of the first insulating layer; and at least partially removing the second insulating layer to increase a bottom critical dimension of the contact hole and removing the overhang portion of the first insulating layer. The invention can secure the bottom critical dimension of the contact hole as well as a distance between the upper portions of the contact holes when the contact plug is formed in a trench in a subsequent process so that the subsequent process margin can be secured. Also, the invention can inhibit an overhang or seam from being formed on the contact plug to enhance contact gap-fill capability and improve contact resistance.

### CROSS-REFERENCE TO RELATED APPLICATION

The priority of Korean Patent Application No. 2007-64306, filed on Jun. 28, 2007, the contents of which are incorporated herein by reference in its entirety, is claimed.

### BACKGROUND OF THE INVENTION

The invention relates to a method of forming a contact plug in a semiconductor device and, more particularly, relates to a method of forming a contact plug in a semiconductor device which can secure a bottom critical dimension of a contact hole as well as a distance between upper portions of contact holes to secure a subsequent process margin.

In a semiconductor device provided with multilayered metal wires, a contact plug is formed by filling a contact hole for electrically connecting an upper element to a lower element. For forming the contact hole in the semiconductor device, an accurate and strict mask alignment is required in the manufacturing process.

A conventional process for forming a contact plug in a semiconductor device is briefly described. First, an interlayer insulating layer is formed on a semiconductor substrate on which certain structures such as a gate and the like are already formed. A certain area of the interlayer insulating layer formed on a junction area formed on the semiconductor substrate is then etched to form a contact hole through which the junction area is exposed. A polysilicon layer is formed on the interlayer insulating layer including the contact hole and then planarized to form a contact plug with which the contact hole is filled.

However, as semiconductor devices have become more highly-integrated, the size of the contact hole has been reduced, and it has become difficult to secure a distance between the contact holes for insulating the contact holes. As such, there is a problem in that, even though a space between top portions of the contact holes is secured due to a large height of the contact hole, a bottom critical dimension of the contact hole cannot be secured. Also, when the contact hole is formed in the above process, if a thickness of an insulating layer to be etched is very thick, a bowing phenomenon in which a depth of mid portion of the contact hole becomes wider is generated. Due to this bowing phenomenon, an overhang portion is formed at an upper portion when a barrier metal layer is formed, and a seam is generated by the overhang portion when a conductive layer for a contact plug is formed. In a case where the seam is generated, it is difficult to gap-fill the contact hole, and so contact resistance is increased.

Furthermore, if the seam is generated, there is a problem in that a tungsten layer is completely removed in the contact hole by hydrogen peroxide (H₂O₂) contained in a slurry during a subsequent chemical mechanical polishing (CMP) process. In this case, the semiconductor device is not operable.

### SUMMARY OF THE INVENTION

The invention provides a method of forming a contact plug in a semiconductor device which can secure a bottom critical dimension of a contact hole and a distance between upper portions of contact holes to secure a subsequent process margin and which can inhibit a seam from being generated to enhance contact gap-fill capability.

A method of forming a contact plug in a semiconductor device according to one embodiment of the invention comprises forming an interlayer insulating layer on a semiconductor substrate; etching the interlayer insulating layer to form a patterned interlayer insulating layer defining a contact hole; forming a first insulating layer wrapping an upper portion of the patterned interlayer insulating layer spaced from the semiconductor substrate, the first insulating layer including a overhang portion; and forming a liner-shaped second insulating layer on the patterned interlayer insulating layer including the first insulating layer including the overhang portion, the second insulating layer having an selectivity which differs from that of the first insulating layer; removing the overhang portion or the first insulating layer; and forming a contact plug in the contact hole.

The contact hole preferably formed such that a critical dimension of the contact hole is increased toward an upper portion from a lower portion. The second insulating layer is preferably partially or entirely removed when the overhang portion is removed. Removing the overhang portion preferably further includes partially or entirely removing the second insulating layer, and removing the first insulating layer by a predetermined thickness.

The first insulating layer is preferably formed of an insulating layer having a poor filling characteristic, and an undoped silicate glass (USG) layer is preferably utilized as the first insulating layer. The first insulating layer preferably has a thickness of 300 Å to 500 Å.

The second insulating layer is preferably formed of a nitride layer and has a thickness of 50 Å to 90 Å. The method preferably further comprises washing after removing the overhang portion. The washing is preferably carried out in a chemical plasma cleaning method. The chemical plasma cleaning method preferably has a higher selectivity with respect to an oxide layer than that with respect to a nitride layer where the first insulating layer comprises an oxide layer and the second insulating layer comprises a nitride layer.

### BRIEF DESCRIPTION OF THE DRAWINGS

The above and other features and advantages of the invention will become readily apparent by reference to the following detailed description when considered in conjunction with the accompanying drawings wherein:

FIG. 1A to FIG. 1H are sectional views of a semiconductor device for illustrating a method of forming a contact plug in a semiconductor device according to one embodiment of the invention.

### DESCRIPTION OF SPECIFIC EMBODIMENTS

Hereinafter, a preferred embodiment of the invention is explained in more detail with reference to the accompanying drawings. However, the embodiments of the invention may be modified variously and the scope of the invention should not be limited to the below embodiment. The description herein is provided for illustrating more completely to those skilled in the art.

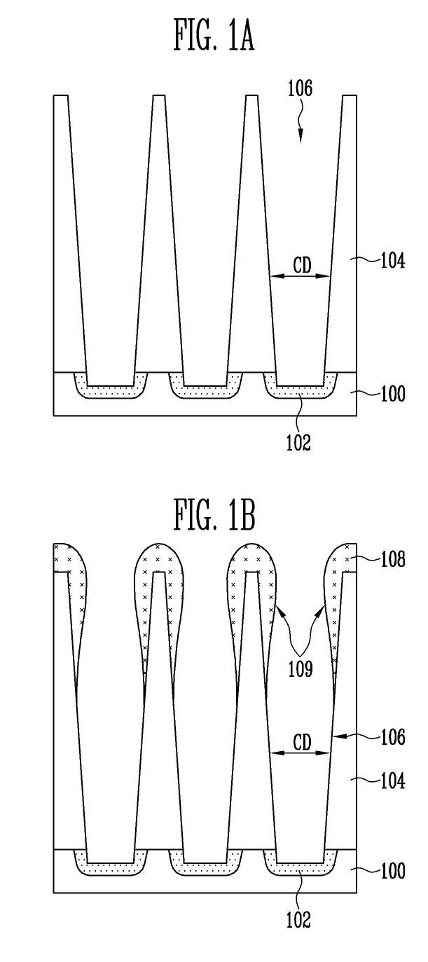

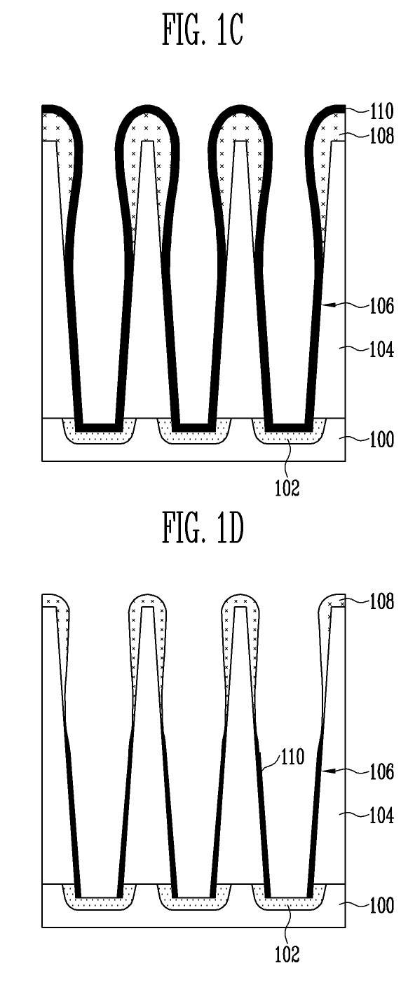

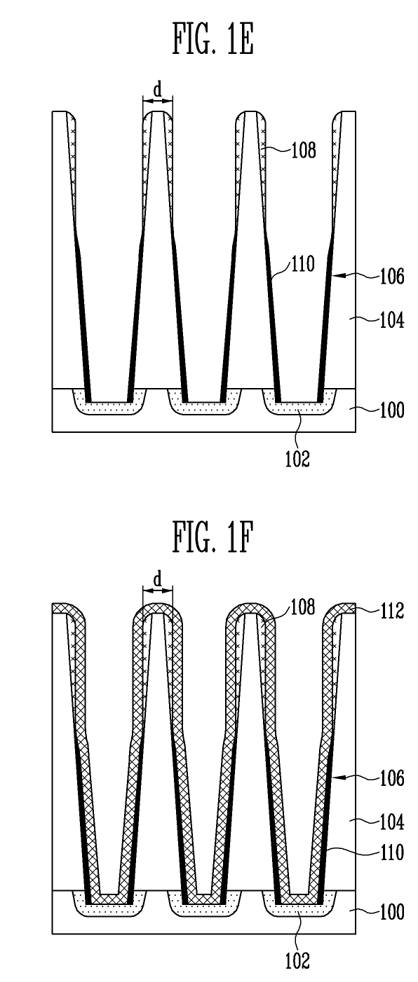

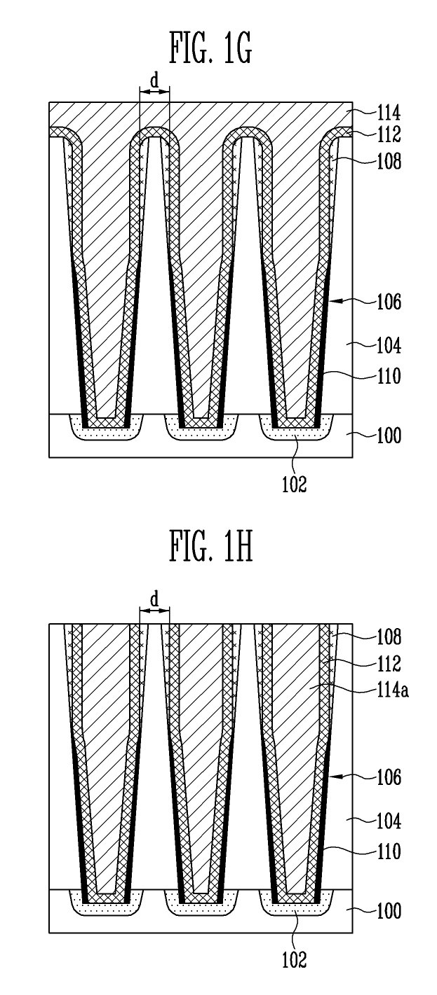

FIG. 1A to FIG. 1H are sectional views of a semiconductor device for illustrating a method of forming a contact plug in a semiconductor device according to one embodiment of the invention.

Referring to FIG. 1A, an interlayer insulating layer 104 is formed on a semiconductor substrate 100 on which junction areas 102 are formed. Any suitable oxidized material can be used for forming the interlayer insulating layer 104. For example, any of SOG (spin on glass), BPSG (boron-phosphorus silicate glass), PETEOS (plasma enhanced tetra Ethyl ortho silicate), USG (undoped silicate glass), PSG (phosphorus silicate glass) and IPO (inter poly oxide) are suitable for forming the interlayer insulating layer.

Then, the interlayer insulating layer 104 placed on the junction areas 102 is etched by an etching process in which a mask (not shown) is utilized. By this etching process, the interlayer insulation layer is patterned, and a contact hole 106 through which the junction area 102 is exposed is formed. At this time, the contact hole 106 is formed such that a critical dimension (CD) of the contact hole is proportionally increased toward an upper portion (away from the substrate 100) from a lower portion (closer to the substrate 100). In the contact hole 106, that is, the critical dimension of a bottom portion is larger than that of a top portion. In particular, the interlayer insulating layer is etched so as to secure a large bottom critical dimension and minimize a distance between upper portions of the contact holes 106.

On the other hand, the mask can be a photoresist pattern. Photoresist is applied on the interlayer insulating layer 104 to form a photoresist layer, the photoresist layer is then patterned by an exposure process and a developing process in which a designed mask is utilized so that the photoresist pattern is formed. Such photoresist pattern is removed after forming the contact hole 106.

Referring to FIG. 1B, a first insulating layer 108 is formed such that the first insulating layer wraps an upper portion of the patterned interlayer insulating layer 104 to form overhang portions 109. To secure a distance between upper portions of the contact holes 106, the first insulating layer 108 is preferably formed from material having a relatively poor filling characteristic, for example, undoped silicate glass (USG). At this time, it is preferable that the first insulating layer 108 has a thickness of 300 Å to 500 Å.

Referring to FIG. 1C, a liner-shaped second insulating layer 110 is formed on the patterned interlayer insulating layer 104 including the first insulating layer 108 having the overhang portions 109. To enable the second insulating layer to be etched selectively during an etching process for enlarging a bottom critical dimension of the contact hole 106, the second insulating layer 110 has a liner shape and is formed from material having an selectivity which differs from that of the first insulating layer 108. Preferably, the second insulating layer 110 is formed of a nitride layer and has a thickness of 50 Å to 90 Å.

Referring to FIG. 1D, an etching process is carried out for removing the overhang portions of the first insulating layer 108. A dry etching process, highly preferably an etchback process, is preferably performed as the etching process. The etchback process is preferably performed utilizing an etching recipe having a higher selectivity with respect to the second insulating layer 110 than that with respect to the first insulating layer 108.

In one preferred embodiment of the invention, wherein the first insulating layer 108 is formed of an oxide layer and the second insulating layer 110 is formed of a nitride layer, the etchback process is carried out using the etching recipe having a higher selectivity with respect to the nitride insulating layer than that with respect to the oxide layer. From this, the second insulating layer 110 formed on a bottom surface and a side surface of the contact hole 106 is selectively etched to increase the bottom critical dimension of the contact hole 106. In addition, during the etching process for the second insulating layer 110, some of the first insulating layer with a certain thickness and width is also etched so that the overhang portion is removed. In the meantime, the second insulating layer 110 is not removed completely in the etching process, but a portion of the second insulating layer may be remained on the side wall of the contact hole 106.

Referring to FIG. 1E, a cleaning process is carried out. As the cleaning process, a dry cleaning process is preferably performed utilizing the chemical plasma cleaning method in which ammonium fluoride (NHₓF_{y})-based active ions (for example, NH₄F, NH₄F.HF) which was already activated by the plasma are utilized. An etching mechanism for the silicon oxide (SiO₂) layer generated when the chemical plasma etching process is performed is briefly illustrated with reference to the below chemical equations.

NF₃+NH₃→NH₄F+NH₄F.HF [Chemical equation 1]

NH₄F+NH₄F.HF+SiO₂→(NH₄)₂SiF₆+H₂O(30° C.) [Chemical equation 2]

(NH₄)₂SiF₆(S)→SiF₄+NH₃+HF(100° C. or more) [Chemical equation 3]

In the chemical plasma etching process, inert gas (NH₃) and ammonium fluoride gas (NF₃) are supplied into a plasma chamber, hydrogen ion (H+) activated by the plasma collides with ammonium fluoride gas (NF₃) to make ammonium fluoride-based active ion (NH₄F.HF) (chemical equation 1). Once the etching process for the silicon oxide (SiO₂) layer is performed using such ammonium fluoride-based active ion (NH₄F.HF), ammonium fluoride-based active ion (NH₄F.HF) severs a Si—O bond of the silicon oxide (SiO₂) layer having the polarizing bond so that ammonium fluoride-based active ion is changed into ammonium fluoride salt ((NH₄)₂SiF₆) to etch the silicon oxide (SiO₂) layer (chemical equation 2). If ammonium fluoride salt ((NH₄)₂SiF₆) obtained during the etching process is heated above a temperature of 100° C., ammonium fluoride salt is resolved into SiF₄, NH₃, HF, and the like and then removed (chemical equation 3). At this time, in the above chemical plasma cleaning process, a selectivity between SiO₂ and Si is approximately 20:1 and a selectivity between SiO₂ and SiN is approximately 5:1, for example.

Thus, the first insulating layer 108 remaining on an upper portion of the interlayer insulating layer 108 is additionally etched by a predetermined thickness and width through the chemical plasma cleaning method having a higher selectivity with respect to the first insulating layer 108 (e.g., the oxide layer) than that with respect to the second insulating layer 110 (e.g., the nitride layer). Accordingly, even though the overhang portion 109 remains on the first insulating layer 108 during the etching process for the second insulating layer 110, the overhang portion is completely removed through the cleaning process.

Thus, in the invention, the first insulating layer 108 remains on an upper portion of the interlayer insulating layer 104, but the overhang portion 109 formed on the first insulating layer 108 is removed. Accordingly, the bottom critical dimension (CD) of the contact hole 106 is increased and a distance (d) (FIG. 1E) between the upper portions of the contact holes 106 is secured to enable a subsequent process margin to be secured. Also, it is possible to inhibit the seam of a barrier metal layer or the conductive layer for the contact plug from being generated to enhance the contact gap-fill capability.

Referring to FIG. 1F, a barrier metal layer 112 is formed on the patterned interlayer layer 104 including the first insulating layer 108. The barrier metal layer 112 is preferably formed of a stack layer consisting of titanium (Ti)/titanium nitride (TiN) for enhancing the adhesive force between the barrier metal layer and a conductive layer to be formed later.

Referring to FIG. 1G, conductive material is deposited on the barrier metal layer 112 including the contact hole 106 to fill the contact hole 106 with conductive material, to form a conductive layer 114. The conductive layer 114 is preferably formed from material having a low resistance, such as tungsten, for example.

In the invention, since the overhang portion is not formed when the barrier metal layer 112 is formed, a seam caused by the overhang portion is not formed at the time of forming the conductive layer 114. Accordingly, a contact gap-fill capability is enhanced to improve a contact resistance so that an operation speed of the semiconductor device can be improved.

Referring to FIG. 1H, the conductive layer 114 is etched until a surface of the interlayer insulating layer 104 is exposed. At this time, as the etching process, a planarization process, preferably a chemical mechanical polishing (CMP) process can be carried out. From this, the conductive layer 114 remains in the contact hole 106 to form a contact plug 114a. And, the distance (d) between the upper portions of the contact holes 106 is secured by the first insulating layer 108 remaining on the upper portion of the interlayer insulating layer 104 so that the subsequent process margin can be secured.

The invention can secure the bottom critical dimension of the drain contact hole as well as a distance between the upper portions of the contact holes to enable the subsequent process margin to be secured.

In the invention, the overhang portion of the insulating layer wrapping the upper portion of the patterned interlayer insulating layer is removed to inhibit the seam from being generated at the time of forming the conductive layer for the contact plug, and so it is possible to enhance the contact gap-fill capability.

In the invention, in addition, the seam is not formed when the contact plug is formed to improve the contact resistance. Consequently, the invention is capable of enhancing an operation speed of the semiconductor device.

Although embodiments have been described with reference to a number of illustrative embodiments thereof, numerous other modifications and embodiments can be envisioned that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of forming a contact plug in a semiconductor device, comprising:
forming an interlayer insulating layer on a semiconductor substrate;
etching the interlayer insulating layer to form a patterned interlayer insulating layer defining a contact hole;
forming a first insulating layer wrapping an upper portion of the patterned interlayer insulating layer spaced from the semiconductor substrate, the first insulating layer including an overhang portion;
forming a liner-shaped second insulating layer on the patterned interlayer insulating layer including the first insulating layer and the overhang portion, the second insulating layer having a selectivity which differs from that of the first insulating layer;
removing the overhang portion of the first insulating layer; and
forming a contact plug in the contact hole.

2. The method of forming a contact plug in a semiconductor device of claim 1, comprising forming the contact hole such that a critical dimension (CD) of the contact hole increases toward an upper portion of the contact hole from a lower portion of the contact hole.

3. The method of forming a contact plug in a semiconductor device of claim 1, comprising partially or entirely removing the second insulating layer when removing the overhang portion.

4. The method of forming a contact plug in a semiconductor device of claim 1, wherein removing the overhang portion further includes:
partially or entirely removing the second insulating layer; and
removing a predetermined thickness of the first insulating layer.

5. The method of forming a contact plug in a semiconductor device of claim 1, comprising forming the first insulating layer of an insulating material having a poor filling characteristic.

6. The method of forming a contact plug in a semiconductor device of claim 5, wherein the insulating material having a poor filling characteristic is undoped silicate glass (USG).

7. The method of forming a contact plug in a semiconductor device of claim 1, wherein the first insulating layer has a thickness of 300 Å to 500 Å.

8. The method of forming a contact plug in a semiconductor device of claim 1, wherein the second insulating layer comprises a nitride layer.

9. The method of forming a contact plug in a semiconductor device of claim 1, wherein the second insulating layer has a thickness of 50 Å to 90 Å.

10. The method of forming a contact plug in a semiconductor device of claim 1, further comprising washing after removing the overhang portion.

11. The method of forming a contact plug in a semiconductor device of claim 10, wherein the washing is carried out by chemical plasma cleaning method.

12. The method of forming a contact plug in a semiconductor device of claim 11, wherein the first insulating layer comprises an oxide layer and the second insulating layer comprises or nitride layer, and the chemical plasma cleaning method has a higher selectivity with respect to an oxide layer than with respect to a nitride layer.
